(19) United States
(12) Patent Application Publication
(10) Pub. No.: US 2025/0362617 A1
(43) Pub. Date: Nov. 27, 2025

(54) METROLOGY METHOD AND ASSOCIATED METROLOGY DEVICE

(71) Applicant: ASML Netherlands B.V., Veldhoven (NL)

(72) Inventors: Olger Victor ZWIER, Eindhoven (NL); Erik Johan KOOP, Eindhoven (NL)

(73) Assignee: ASML Netherlands B.V., Veldhoven (NL)

(21) Appl. No.: 18/874,483

(22) PCT Filed: Jul. 19, 2023
(86) PCT No.: PCT/EP2023/070043

§ 371 Date: Dec. 12, 2024

(30) Foreign Application Priority Data
Aug. 10, 2022 (EP) 22189687.1

(51) Int. Cl. G03F 7/00; G01B 11/27

(52) U.S. Cl. CPC G03F 7/706831; G01B 11/272; G03F 7/70633; G03F 7/70641; G03F 7/70666; G03F 7/706845; G03F 7/706847; G03F 7/706849

(57) ABSTRACT

Disclosed is a metrology method. The method comprises illuminating a target comprising one or more sub-targets on a substrate using underfilled illumination such that an illumination beam profile underfills each of said one or more sub-targets; capturing scattered radiation resultant from said illuminating the target; imaging the scattered radiation at a detection image plane to obtain an image; and determining a parameter of interest from the imaged scattered radiation.

### CROSS-REFERENCE TO RELATED APPLICATIONS

This application claims priority of EP Application Serial No. 22189687.1 which was filed on 10 August 2022 and which is incorporated herein in its entirety by reference.

### FIELD

The present invention relates to a metrology method and device which may, for example, be used for determining a characteristic of structures on a substrate.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) at a patterning device (e.g., a mask) onto a layer of radiation-sensitive material (resist) provided on a substrate (e.g., a wafer).

To project a pattern on a substrate a lithographic apparatus may use electromagnetic radiation. The wavelength of this radiation determines the minimum size of features which can be formed on the substrate. Typical wavelengths currently in use are 365 nm (i-line), 248 nm, 193 nm and 13.5 nm. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

Low-k₁ lithography may be used to process features with dimensions smaller than the classical resolution limit of a lithographic apparatus. In such process, the resolution formula may be expressed as CD=k₁×λ/NA, where λ is the wavelength of radiation employed, NA is the numerical aperture of the projection optics in the lithographic apparatus, CD is the “critical dimension” (generally the smallest feature size printed, but in this case half-pitch) and k₁ is an empirical resolution factor. In general, the smaller k₁ the more difficult it becomes to reproduce the pattern on the substrate that resembles the shape and dimensions planned by a circuit designer in order to achieve particular electrical functionality and performance. To overcome these difficulties, sophisticated fine-tuning steps may be applied to the lithographic projection apparatus and/or design layout. These include, for example, but not limited to, optimization of NA, customized illumination schemes, use of phase shifting patterning devices, various optimization of the design layout such as optical proximity correction (OPC, sometimes also referred to as “optical and process correction”) in the design layout, or other methods generally defined as “resolution enhancement techniques” (RET). Alternatively, tight control loops for controlling a stability of the lithographic apparatus may be used to improve reproduction of the pattern at low k1.

In lithographic processes, it is desirable to make frequently measurements of the structures created, e.g., for process control and verification. Various tools for making such measurements are known, including scanning electron microscopes or various forms of metrology apparatuses, such as scatterometers. A general term to refer to such tools may be metrology apparatuses or inspection apparatuses.

In some metrology methods, the measured target is “overfilled”; i.e., the metrology target is smaller than the measurement spot. This has benefits over more conventional “underfilled” measurements, where the measurement spot is smaller than the target. Overfilled metrology enables smaller targets, and also enables simultaneous acquisition of a number of different sub-targets or target pads. It also enables algorithms to be used which enable selection of particular target areas (e.g., pixel mapping).

However, overfilled metrology is susceptible to edge effects. Edge effects often manifest as brighter (or less bright) regions along one or more edges of one or more of the pads; these brighter regions also affect the region of interest of the sub-target being considered.

It is desirable to mitigate for such edge effects.

### SUMMARY

Embodiments of the invention are disclosed in the claims and in the detailed description.

In a first aspect of the invention there is provided a metrology method comprising: illuminating a target comprising one or more sub-targets on a substrate using underfilled illumination such that an illumination beam profile underfills each of said one or more sub-targets; capturing scattered radiation resultant from said illuminating the target; imaging the scattered radiation at a detection image plane to obtain an image; and determining a parameter of interest from the imaged scattered radiation.

In a second aspect of the invention there is provided a metrology method comprising: illuminating a target comprising a plurality of sub-targets on a substrate by simultaneously illuminating each sub-target using a configured illumination beam profile which is configured for individually illuminating each of said plurality of sub-targets; capturing scattered radiation resultant from said illuminating the target; and determining a parameter of interest from the scattered radiation

The invention yet further provides a metrology device operable to perform the method of the first aspect or second aspect.

These and other aspects and advantages of the apparatus and methods disclosed herein will be appreciated from a consideration of the following description and drawings of exemplary embodiments.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 depicts a schematic overview of a lithographic cell;

FIG. 3 depicts a schematic representation of holistic lithography, representing a cooperation between three key technologies to optimize semiconductor manufacturing;

FIG. 4 is a schematic illustration of a scatterometry apparatus;

FIG. 5 comprises (a) a schematic diagram of a dark field scatterometer for use in measuring targets according to embodiments of the invention using a first pair of illumination apertures, (b) a detail of diffraction spectrum of a target grating for a given direction of illumination (c) a second pair of illumination apertures providing further illumination modes in using the scatterometer for diffraction based overlay measurements (d) a third pair of illumination apertures combining the first and second pair of apertures;

FIG. 6 depicts a known form of multiple grating (or multiple sub-target) target and an outline of a measurement spot on a substrate for a known overfilled measurement method;

FIG. 7 depicts an image of the target of FIG. 6 obtained in the scatterometer of FIG. 5(a); and

FIG. 8 depicts the target of FIG. 6 and an outline of a measurement spot on a substrate configured according to an embodiment.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

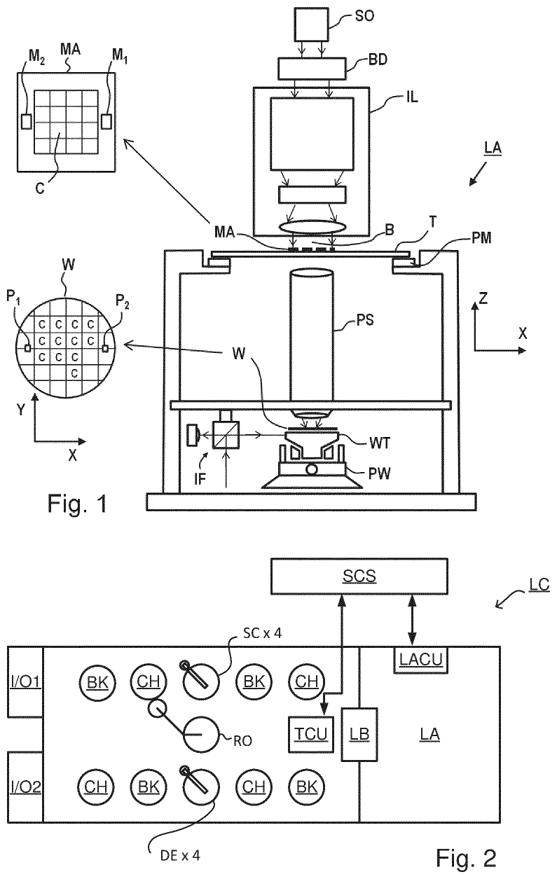

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W-which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

As shown in FIG. 2 the lithographic apparatus LA may form part of a lithographic cell LC, also sometimes referred to as a lithocell or (litho)cluster, which often also includes apparatus to perform pre- and post-exposure processes on a substrate W. Conventionally these include spin coaters SC to deposit resist layers, developers DE to develop exposed resist, chill plates CH and bake plates BK, e.g. for conditioning the temperature of substrates W e.g. for conditioning solvents in the resist layers. A substrate handler, or robot, RO picks up substrates W from input/output ports I/O1, I/O2, moves them between the different process apparatus and delivers the substrates W to the loading bay LB of the lithographic apparatus LA. The devices in the lithocell, which are often also collectively referred to as the track, are typically under the control of a track control unit TCU that in itself may be controlled by a supervisory control system SCS, which may also control the lithographic apparatus LA, e.g. via lithography control unit LACU.

In order for the substrates W exposed by the lithographic apparatus LA to be exposed correctly and consistently, it is desirable to inspect substrates to measure properties of patterned structures, such as overlay errors between subsequent layers, line thicknesses, critical dimensions (CD), etc. For this purpose, inspection tools (not shown) may be included in the lithocell LC. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus, which may also be referred to as a metrology apparatus, is used to determine properties of the substrates W, and in particular, how properties of different substrates W vary or how properties associated with different layers of the same substrate W vary from layer to layer. The inspection apparatus may alternatively be constructed to identify defects on the substrate W and may, for example, be part of the lithocell LC, or may be integrated into the lithographic apparatus LA, or may even be a stand-alone device. The inspection apparatus may measure the properties on a latent image (image in a resist layer after the exposure), or on a semi-latent image (image in a resist layer after a post-exposure bake step PEB), or on a developed resist image (in which the exposed or unexposed parts of the resist have been removed), or even on an etched image (after a pattern transfer step such as etching).

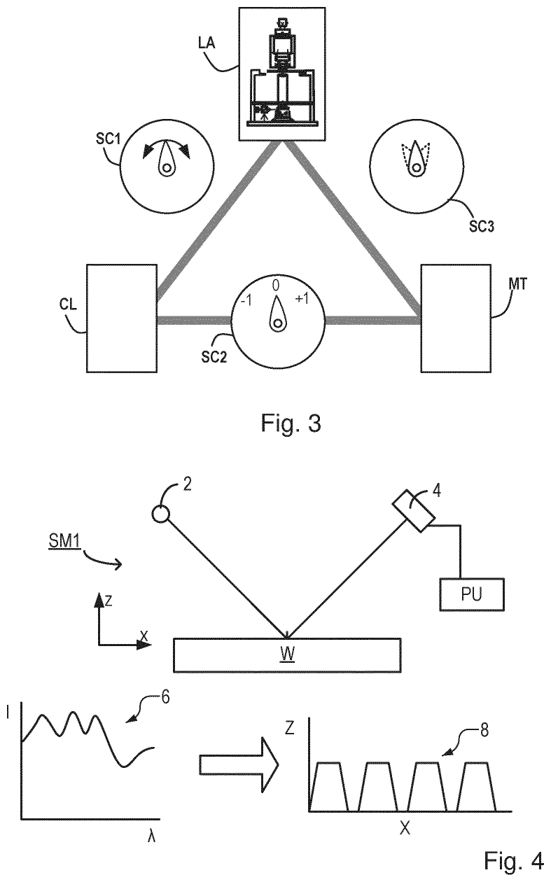

Typically the patterning process in a lithographic apparatus LA is one of the most critical steps in the processing which requires high accuracy of dimensioning and placement of structures on the substrate W. To ensure this high accuracy, three systems may be combined in a so called “holistic” control environment as schematically depicted in FIG. 3. One of these systems is the lithographic apparatus LA which is (virtually) connected to a metrology tool MET (a second system) and to a computer system CL (a third system). The key of such “holistic” environment is to optimize the cooperation between these three systems to enhance the overall process window and provide tight control loops to ensure that the patterning performed by the lithographic apparatus LA stays within a process window. The process window defines a range of process parameters (e.g. dose, focus, overlay) within which a specific manufacturing process yields a defined result (e.g. a functional semiconductor device)-typically within which the process parameters in the lithographic process or patterning process are allowed to vary.

The computer system CL may use (part of) the design layout to be patterned to predict which resolution enhancement techniques to use and to perform computational lithography simulations and calculations to determine which mask layout and lithographic apparatus settings achieve the largest overall process window of the patterning process (depicted in FIG. 3 by the double arrow in the first scale SC1). Typically, the resolution enhancement techniques are arranged to match the patterning possibilities of the lithographic apparatus LA. The computer system CL may also be used to detect where within the process window the lithographic apparatus LA is currently operating (e.g. using input from the metrology tool MET) to predict whether defects may be present due to e.g. sub-optimal processing (depicted in FIG. 3 by the arrow pointing “0” in the second scale SC2).

The metrology tool MET may provide input to the computer system CL to enable accurate simulations and predictions, and may provide feedback to the lithographic apparatus LA to identify possible drifts, e.g. in a calibration status of the lithographic apparatus LA (depicted in FIG. 3 by the multiple arrows in the third scale SC3).

In lithographic processes, it is desirable to make frequently measurements of the structures created, e.g., for process control and verification. Various tools for making such measurements are known, including scanning electron microscopes or various forms of metrology apparatuses, such as scatterometers. Examples of known scatterometers often rely on provision of dedicated metrology targets, such as underfilled targets (a target, in the form of a simple grating or overlapping gratings in different layers, that is large enough that a measurement beam generates a spot that is smaller than the grating) or overfilled targets (whereby the illumination spot partially or completely contains the target).

Further, the use of metrology tools, for example an angular resolved scatterometer illuminating an underfilled target, such as a grating, allows the use of so-called reconstruction methods where the properties of the grating can be calculated by simulating interaction of scattered radiation with a mathematical model of the target structure and comparing the simulation results with those of a measurement. Parameters of the model are adjusted until the simulated interaction produces a diffraction pattern similar to that observed from the real target.

Scatterometers are versatile instruments which allow measurements of the parameters of a lithographic process by having a sensor in the pupil or a conjugate plane with the pupil of the objective of the scatterometer, measurements usually referred as pupil based measurements, or by having the sensor in the image plane or a plane conjugate with the image plane, in which case the measurements are usually referred as image or field based measurements. Such scatterometers and the associated measurement techniques are further described in patent applications US20100328655, US2011102753A1, US20120044470A, US20110249244, US20110026032 or EP1,628,164A, incorporated herein by reference in their entirety. Aforementioned scatterometers can measure in one image multiple targets from multiple gratings using light from soft x-ray and visible to near-IR wave range.

A metrology apparatus, such as a scatterometer, is depicted in FIG. 4. It comprises a broadband (white light) radiation projector 2 which projects radiation 5 onto a substrate W. The reflected or scattered radiation 10 is passed to a spectrometer detector 4, which measures a spectrum 6 (i.e. a measurement of intensity I as a function of wavelength 2) of the specular reflected radiation 10. From this data, the structure or profile 8 giving rise to the detected spectrum may be reconstructed by processing unit PU, e.g. by Rigorous Coupled Wave Analysis and non-linear regression or by comparison with a library of simulated spectra. In general, for the reconstruction, the general form of the structure is known and some parameters are assumed from knowledge of the process by which the structure was made, leaving only a few parameters of the structure to be determined from the scatterometry data. Such a scatterometer may be configured as a normal-incidence scatterometer or an oblique-incidence scatterometer.

In a first embodiment, the scatterometer MT is an angular resolved scatterometer. In such a scatterometer reconstruction methods may be applied to the measured signal to reconstruct or calculate properties of the grating. Such reconstruction may, for example, result from simulating interaction of scattered radiation with a mathematical model of the target structure and comparing the simulation results with those of a measurement. Parameters of the mathematical model are adjusted until the simulated interaction produces a diffraction pattern similar to that observed from the real target.

In a second embodiment, the scatterometer MT is a spectroscopic scatterometer MT. In such spectroscopic scatterometer MT, the radiation emitted by a radiation source is directed onto the target and the reflected or scattered radiation from the target is directed to a spectrometer detector, which measures a spectrum (i.e. a measurement of intensity as a function of wavelength) of the specular reflected radiation. From this data, the structure or profile of the target giving rise to the detected spectrum may be reconstructed, e.g. by Rigorous Coupled Wave Analysis and non-linear regression or by comparison with a library of simulated spectra.

In a third embodiment, the scatterometer MT is an ellipsometric scatterometer. The ellipsometric scatterometer allows for determining parameters of a lithographic process by measuring scattered radiation for each polarization states. Such metrology apparatus emits polarized light (such as linear, circular, or elliptic) by using, for example, appropriate polarization filters in the illumination section of the metrology apparatus. A source suitable for the metrology apparatus may provide polarized radiation as well. Various embodiments of existing ellipsometric scatterometers are described in U.S. patent application Ser. Nos. 11/451,599, 11/708,678, 12/256,780, 12/486,449, 12/920,968, 12/922,587, 13/000,229, 13/033,135, 13/533,110 and 13/891,410 incorporated herein by reference in their entirety.

In one embodiment of the scatterometer MT, the scatterometer MT is adapted to measure the overlay of two misaligned gratings or periodic structures by measuring asymmetry in the reflected spectrum and/or the detection configuration, the asymmetry being related to the extent of the overlay. The two (typically overlapping) grating structures may be applied in two different layers (not necessarily consecutive layers), and may be formed substantially at the same position on the wafer. The scatterometer may have a symmetrical detection configuration as described e.g. in co-owned patent application EP1,628,164A, such that any asymmetry is clearly distinguishable. This provides a straightforward way to measure misalignment in gratings. Further examples for measuring overlay error between the two layers containing periodic structures as target is measured through asymmetry of the periodic structures may be found in PCT patent application publication no. WO 2011/012624 or US patent application US20160161863, incorporated herein by reference in its entirety. Other parameters of interest may be focus and dose. Focus and dose may be determined simultaneously by scatterometry (or alternatively by scanning electron microscopy) as described in US patent application US2011-0249244, incorporated herein by reference in its entirety.

The targets may be measured in an underfilled mode or in an overfilled mode. In the underfilled mode, the measurement beam generates a spot that is smaller than the overall target. In the overfilled mode, the measurement beam generates a spot that is larger than the overall target. In such overfilled mode, it may also be possible to measure different targets simultaneously, thus determining different processing parameters at the same time.

Overall measurement quality of a lithographic parameter using a specific target is at least partially determined by the measurement recipe used to measure this lithographic parameter. The term “substrate measurement recipe” may include one or more parameters of the measurement itself, one or more parameters of the one or more patterns measured, or both. For example, if the measurement used in a substrate measurement recipe is a diffraction-based optical measurement, one or more of the parameters of the measurement may include the wavelength of the radiation, the polarization of the radiation, the incident angle of radiation relative to the substrate, the orientation of radiation relative to a pattern on the substrate, etc. One of the criteria to select a measurement recipe may, for example, be a sensitivity of one of the measurement parameters to processing variations. More examples are described in US patent application US2016-0161863 and published US patent application US 2016/0370717A1 incorporated herein by reference in its entirety.

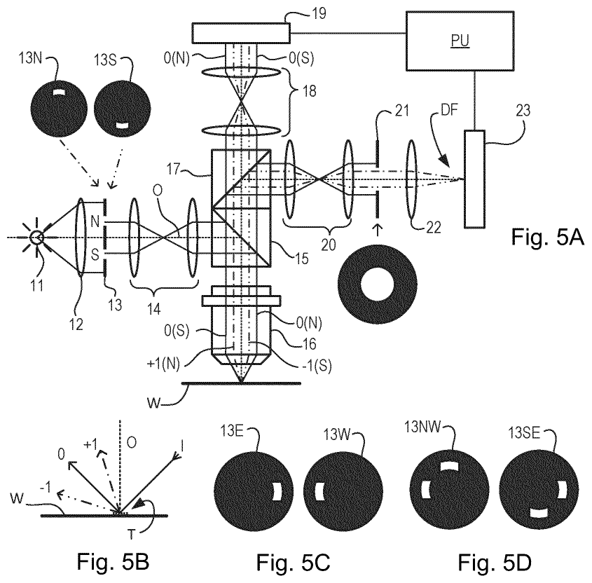

FIG. 5(a) presents an embodiment of a metrology apparatus and, more specifically, a dark field scatterometer. A target T and diffracted rays of measurement radiation used to illuminate the target are illustrated in more detail in FIG. 5(b). The metrology apparatus illustrated is of a type known as a dark field metrology apparatus. The metrology apparatus may be a stand-alone device or incorporated in either the lithographic apparatus LA, e.g., at the measurement station, or the lithographic cell LC. An optical axis, which has several branches throughout the apparatus, is represented by a dotted line O. In this apparatus, light emitted by source 11 (e.g., a xenon lamp) is directed onto substrate W via a beam splitter 15 by an optical system comprising lenses 12, 14 and objective lens 16. These lenses are arranged in a double sequence of a 4F arrangement. A different lens arrangement can be used, provided that it still provides a substrate image onto a detector, and simultaneously allows for access of an intermediate pupil-plane for spatial-frequency filtering. Therefore, the angular range at which the radiation is incident on the substrate can be selected by defining a spatial intensity distribution in a plane that presents the spatial spectrum of the substrate plane, here referred to as a (conjugate) pupil plane. In particular, this can be done by inserting an aperture plate 13 of suitable form between lenses 12 and 14, in a plane which is a back-projected image of the objective lens pupil plane. In the example illustrated, aperture plate 13 has different forms, labeled 13N and 13S, allowing different illumination modes to be selected. The illumination system in the present examples forms an off-axis illumination mode. In the first illumination mode, aperture plate 13N provides off-axis from a direction designated, for the sake of description only, as ‘north’. In a second illumination mode, aperture plate 13S is used to provide similar illumination, but from an opposite direction, labeled ‘south’. Other modes of illumination are possible by using different apertures. The rest of the pupil plane is desirably dark as any unnecessary light outside the desired illumination mode will interfere with the desired measurement signals.

As shown in FIG. 5(b), target T is placed with substrate W normal to the optical axis O of objective lens 16. The substrate W may be supported by a support (not shown). A ray of measurement radiation I impinging on target T from an angle off the axis O gives rise to a zeroth order ray (solid line 0) and two first order rays (dot-chain line +1 and double dot-chain line −1). It should be remembered that with an overfilled small target, these rays are just one of many parallel rays covering the area of the substrate including metrology target T and other features. Since the aperture in plate 13 has a finite width (necessary to admit a useful quantity of light, the incident rays I will in fact occupy a range of angles, and the diffracted rays 0 and +1/−1 will be spread out somewhat. According to the point spread function of a small target, each order +1 and −1 will be further spread over a range of angles, not a single ideal ray as shown. Note that the grating pitches of the targets and the illumination angles can be designed or adjusted so that the first order rays entering the objective lens are closely aligned with the central optical axis. The rays illustrated in FIGS. 5(a) and 5(b) are shown somewhat off axis, purely to enable them to be more easily distinguished in the diagram.

At least the 0 and +1 orders diffracted by the target T on substrate W are collected by objective lens 16 and directed back through beam splitter 15. Returning to FIG. 5(a), both the first and second illumination modes are illustrated, by designating diametrically opposite apertures labeled as north (N) and south(S). When the incident ray I of measurement radiation is from the north side of the optical axis, that is when the first illumination mode is applied using aperture plate 13N, the +1 diffracted rays, which are labeled +1 (N), enter the objective lens 16. In contrast, when the second illumination mode is applied using aperture plate 13S the −1 diffracted rays (labeled 1(S)) are the ones which enter the lens 16.

A second beam splitter 17 divides the diffracted beams into two measurement branches. In a first measurement branch, optical system 18 forms a diffraction spectrum (pupil plane image) of the target on first sensor 19 (e.g. a CCD or CMOS sensor) using the zeroth and first order diffractive beams. Each diffraction order hits a different point on the sensor, so that image processing can compare and contrast orders. The pupil plane image captured by sensor 19 can be used for focusing the metrology apparatus and/or normalizing intensity measurements of the first order beam. The pupil plane image can also be used for many measurement purposes such as reconstruction.

In the second measurement branch, optical system 20, 22 forms an image of the target T on sensor 23 (e.g. a CCD or CMOS sensor). In the second measurement branch, an aperture stop 21 is provided in a plane that is conjugate to the pupil-plane. Aperture stop 21 functions to block the zeroth order diffracted beam so that the image of the target formed on sensor 23 is formed only from the −1 or +1 first order beam. The images captured by sensors 19 and 23 are output to processor PU which processes the image, the function of which will depend on the particular type of measurements being performed. Note that the term ‘image’ is used here in a broad sense. An image of the grating lines as such will not be formed, if only one of the −1 and +1 orders is present.

The particular forms of aperture plate 13 and field stop 21 shown in FIG. 5 are purely examples. In another embodiment of the invention, on-axis illumination of the targets is used and an aperture stop with an off-axis aperture is used to pass substantially only one first order of diffracted light to the sensor. In yet other embodiments, 2nd, 3rd and higher order beams (not shown in FIG. 5) can be used in measurements, instead of or in addition to the first order beams.

In order to make the measurement radiation adaptable to these different types of measurement, the aperture plate 13 may comprise a number of aperture patterns formed around a disc, which rotates to bring a desired pattern into place. Note that aperture plate 13N or 13S can only be used to measure gratings oriented in one direction (X or Y depending on the set-up). For measurement of an orthogonal grating, rotation of the target through 90° and 270° might be implemented. Different aperture plates are shown in FIGS. 5(c) and (d). The use of these, and numerous other variations and applications of the apparatus are described in prior published applications, mentioned above.

As an alternative to a scatterometer, a metrology device may comprise a holographic microscope such as a digital holographic microscope or digital dark-field holographic microscope. Such as device is disclosed, for example, in WO2021121733A1 which is incorporated herein by reference.

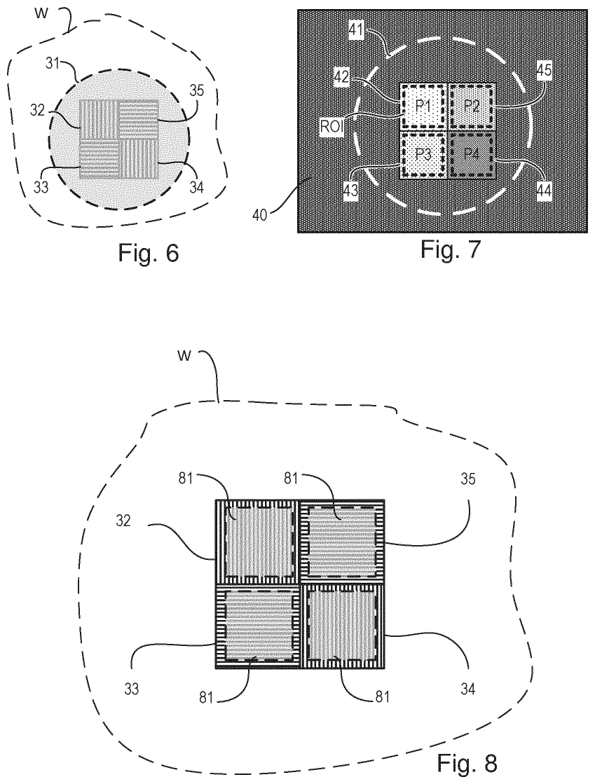

FIG. 6 depicts an overlay target or composite overlay target formed on a substrate according to known practice. The overlay target in this example comprises four sub-targets (e.g., gratings) 32 to 35 positioned closely together so that they will all be within a measurement spot 31 formed by the metrology radiation illumination beam of the metrology apparatus (i.e., the target is overfilled). The four sub-overlay targets thus are all simultaneously illuminated and simultaneously imaged on sensor 23. In an example dedicated to measurement of overlay, sub-targets 32 to 35 are themselves composite structures formed by overlying gratings that are patterned in different layers of the semi-conductor device formed on substrate W. Sub-targets 32 to 35 may have differently biased overlay offsets in order to facilitate measurement of overlay between the layers in which the different parts of the composite sub-targets are formed. The meaning of overlay bias will be explained below with reference to FIG. 7. Sub-targets 32 to 35 may also differ in their orientation, as shown, so as to diffract incoming radiation in X and Y directions. In one example, sub-targets 32 and 34 are X-direction sub-targets with biases of the +d, −d, respectively. Sub-targets 33 and 35 are Y-direction sub-targets with offsets +d and −d respectively. Separate images of these sub-targets can be identified in the image captured by sensor 23. This is only one example of an overlay target. An overlay target may comprise more or fewer than four sub-targets.

FIG. 7 shows an example of an image that may be formed on and detected by the sensor 23, using the overlay target of FIG. 6 in the apparatus of FIG. 5(a), using the aperture plates 13NW or 13SE from FIG. 5(d). While the pupil plane image sensor 19 cannot resolve the different individual sub-targets 32 to 35, the image sensor 23 can do so. The hatched area 40 represents the field of the image on the sensor, within which the illuminated spot 31 on the substrate is imaged into a corresponding circular area 41. Within this, rectangular areas 42-45 represent the images of the small overlay target sub-targets 32 to 35. If the overlay targets are located in product areas, product features may also be visible in the periphery of this image field. Image processor and controller PU processes these images using pattern recognition to identify the separate images 42 to 45 of sub-targets 32 to 35. In this way, the images do not have to be aligned very precisely at a specific location within the sensor frame, which greatly improves throughput of the measuring apparatus as a whole.

Once the separate images of the overlay targets have been identified, the intensities of those individual images can be measured, e.g., by averaging or summing selected pixel intensity values within the identified areas. Intensities and/or other properties of the images can be compared with one another. These results can be combined to measure different parameters of the lithographic process. Overlay performance is an important example of such a parameter.

One known metrology method which may be performed using a metrology tool such as illustrated in FIG. 5(a) is known as diffraction based overlay (DBO) or micro-diffraction based overlay (μDBO). Such μDBO techniques use the imaging branch (the branch through detector 23) of the metrology tool, and determine asymmetry in a structure based on an intensity or diffraction efficiency asymmetry or intensity or diffraction efficiency difference between a first diffraction order and a second diffraction order of a pair of complementary pair of diffraction orders (typically a complementary pair of first diffraction orders, i.e., the first diffraction order may comprise the +1 order and the second diffraction order may comprise the −1 order as illustrated in FIG. 5(b)). As such, in this context, the terms “first” and “second” do not refer to a diffraction order number and are simply being used to distinguish the two diffractions orders of a complementary pair, noting that the first and second diffraction orders may be the +2 and −2 diffraction orders or a higher pair of complementary diffraction orders. The zeroth order (specular radiation) is typically blocked or diverted elsewhere (e.g., to another part of the detector for monitoring purposes); it is not used in μDBO metrology. The main “images” used for parameter of interest inference are formed only from higher (e.g., first) diffraction orders. The asymmetry of the structure may be used to infer a parameter of interest such as overlay or focus, depending on the target design.

The measurement parameter (e.g., intensity, amplitude or diffraction efficiency) may be determined from the captured μDBO camera images by finding the target position and integrating a certain region of interest (ROI) within the camera images, e.g., to provide a single value for the measurement parameter for each sub-target. However, a measurement image may show a significant measurement parameter deviation from the average value over the region of interest at one or more edges of one or more sub-targets of an imaged target. This measurement parameter deviation may be referred to as an edge effect. In many cases, it manifests as a region of higher intensity (or related parameter) at the target edge, although it may also manifest as a region of lower intensity. In either case, this edge effect can impact the intensity/measurement parameter within the region of interest, and therefore impact parameter of interest (e.g., overlay) inference from the measurement parameter. As targets become smaller (e.g., 5 μm square and smaller), the edge effects become more significant and more difficult to deal with using known methods. In addition, edge effect from the surroundings may also present an issue.

The reason that edge effects are a problem is that many metrology techniques, such as μDBO or its focus metrology equivalent μDBF (where the targets have a scanner focus dependent asymmetry rather than an overlay dependent asymmetry) use overfilled metrology where the entire target (which may be composite targets comprising multiple individual sub-targets) are smaller and fully contained within the measurement spot used to measure the target. This is the situation illustrated in FIG. 6, described above. In an overfilled measurement, the target edges, surrounding structure and other sub-targets are captured and imaged in each measurement image. As targets become smaller, the ratio of target diffraction versus unwanted edge effect diffraction becomes smaller and the it becomes more difficult to find a section of the target pad which is “clean”, i.e., only contains proper parameter of interest information.

Overfilled metrology has the advantage of being fast; it allows multiple sub-targets to be measured simultaneously, with regions of interest ROI selected from each sub-target based on the image. More complex algorithms for selecting portions of the imaged target are also possible, such as pixel mapping. These benefits in speed and image portion selection are not possible with underfilled metrology techniques which use measurement spots that are smaller than each sub-target to underfill each sub-target sequentially and individually. On the other hand, underfilled metrology can provide the advantage of not being subject to edge effects, as edges and surrounding structure or other sub-targets are not captured in the measurement spot and therefore do not affect the image. However, this is only true if executed perfectly, since making a spot sufficiently small to underfill a target presents its own challenges and limits.

As has been described, overfilled metrology methods such as μDBO and μDBF typically capture images at an image plane, or conjugate thereof, of the metrology tool's imaging optics. Each of these images are typically formed from single diffraction orders (e.g., +1 and −1 diffraction orders), although images of two or more diffraction orders may be imaged simultaneously on different areas in a single composite image (i.e., separated at a detection image plane). This is in contrast to underfilled metrology methods, which create “images” at a pupil plane (or conjugate thereof) of the metrology tool's imaging optics, i.e., angularly resolved images of the target. With reference to a metrology tool of the type illustrated in FIG. 5(a), overfilled metrology may use an imaging branch of a type comprising a detector 23 at an image plane, and underfilled metrology may use an imaging branch of a type comprising a detector 19 at a pupil plane (or Fourier plane).

A metrology method is proposed comprising: illuminating a target on a substrate using underfilled illumination; capturing scattered radiation resultant from said illuminating the target; imaging the scattered radiation at an image plane; and determining a parameter of interest from the imaged scattered radiation.

The first step may comprise illuminating the target such that an illumination beam profile (e.g., measurement spot) on the target is optimized to illuminate one or more target regions corresponding to one or more regions of interest on a detected image at a detection image plane while minimizing illumination of nuisance structures (e.g., target edges and/or surrounding structure) on said substrate outside of said one or more target regions.

A metrology method is also proposed, comprising illuminating a target comprising a plurality of sub-targets on a substrate by simultaneously illuminating each sub-target using a configured illumination beam profile which is configured for individually illuminating each of said plurality of sub-targets; capturing scattered radiation resultant from said illuminating the target; and determining a parameter of interest from the scattered radiation. This embodiment may capture the scattered radiation at an image plane and/or at a pupil plane.

In an embodiment, the target comprises two or more sub-targets, the illuminating step comprises simultaneously illuminating each sub-target using underfilled illumination, and the capturing step comprises simultaneously capturing scattered radiation resultant from said illuminating each sub-target. In this way the scattered radiation from each target will be simultaneously imaged at the image plane.

Methods will now be described for performing the illuminating step, e.g., for optimizing the illumination beam profile onto the target. The optimization may be such that nothing is illuminated which is not to be measured (e.g., no target edges or surrounding structure is illuminated). However, the measurement spot should not be too small as this results in a large sensitivity to spot position on the target. As such, the optimization may maximize the area of each sub-target illuminated, or at least ensure a sufficiently large area of each sub-target is illuminated. Such a measurement spot should be positioned extremely precisely, so as not to clip any target edge. Because of this, a tolerance may be added when determining the spot size to provide some latitude in measurement spot placement, although this reduces the spot size further.

In a first embodiment, a spot size selector is proposed, which can be dynamically controlled so as to configure the illumination such that only parts of the target corresponding to regions of interest (ROI) on the resultant image are illuminated. An algorithm may be used to perform the ROI identification and to control the illumination configuration based on the ROI identification. This ROI identification and illumination configuration may be performed inline, at least for a subset of the measured targets.

In an embodiment, such a method may comprise illuminating the target in an overfilled manner, i.e., such that the full spot illuminates the entire target, including edges. A pattern recognition step can then be performed to identify the locations of the ROIs. The illumination can then be configured such that any illumination illuminating target regions not corresponding to ROIs on the image can be switched off or blocked such that only target regions corresponding to ROIs are illuminated. This is only an example of an illumination strategy. It may be that for a particular target, layer and environment, edge effects at the boundary of the sub-target are not a problem or not so much of problem; instead a very “bright” feature (as imaged), e.g., somewhat further away, may be a much more significant problem. In such a case, it may be preferred to illuminate the full pad (e.g., including one or more edges), but not the very bright feature. This would eliminate crosstalk from the problem feature, but loosen the tight positioning spec that the proposed methodology might otherwise require. As such, the illumination may also be configured to illuminate only regions which do not contribute to undesirable crosstalk.

Once the illumination beam profile is suitably configured or optimized, an (e.g., underfilled) measurement may be performed using the configured illumination beam profile. While the method may be performed on a single ROI target (e.g., a target undivided into or not comprising separate sub-targets), it is preferable in terms of speed and throughput that targets comprising multiple sub-targets are measurable in this manner (e.g., targets such as illustrated in FIG. 6), with the sub-targets being measured together and simultaneously. As such, the configured illumination beam profile may be configured to illuminate the different sub-targets individually without illuminating their edges or any neighboring structure. The resultant scattered illumination may then be imaged at an image plane, e.g., such that different sub-targets for each of the diffraction orders of a complementary pair (e.g., +1 and −1 diffraction orders) are imaged separately at different regions of the detection image plane.

In an optional embodiment, it may be possible to tune the relative intensity of the (e.g., underfilled) illumination areas per sub-target. This may comprise optimizing the relative intensity to further reduce crosstalk (e.g., by varying the relative intensity between the X sub-targets and Y sub-targets of a target). That may enable an increase in the dynamic range of the system, which can then measure the two directions simultaneously, even though one direction is much brighter under normal, homogeneous, single-spot illumination (i.e. the brighter direction won't saturate the camera, or cause some residual intra-target leakage). In an extreme variation of such an approach, the X sub-targets and Y sub-targets may be illuminated separately; for example should this be optimal for intra-target crosstalk, and if the X sub-targets and Y sub-targets were to be measured with separate profiles in any case.

FIG. 8 illustrates the measurement of a target such as a typical μDBO target measured using measurement illumination configured according to the concepts disclosed herein. The only difference compared to the example of FIG. 6, is that the measurement illumination no longer comprises a single measurement spot 31 encompassing the entire target, but rather the measurement illumination comprises four configured measurement spots 81, each configured for a respective target region corresponding to a region of interest (e.g., referring to the ROIs in FIG. 7) of each sub-target 32-34.

Where the illuminator, illumination arrangement or spot size selector is a programmable illuminator or pixel-based illuminator (e.g., an illumination arrangement which uses a spatial light modulator (SLM) or a grating light valve (GLV) technology), this control can be done via illumination pixels on (for example) a per-pixel basis. GLV technology is marketed by Silicon Light Machines (SLM) and is described in U.S. Pat. No. 6,947,613B. Such an illuminator or illumination arrangement may be located, for example, in an illumination image plane (i.e., an image plane within an illumination branch of the metrology tool).

This approach enables underfilled metrology to be performed on multiple targets or sub-targets simultaneously therefore preventing any stray light from illuminating surroundings and edges (both inside and outside the target), while obviating the need for extremely accurate alignment of illumination on the target.

The first step of the proposed method can be performed coarsely, e.g., using a very low integration time during pattern recognition/ROI identification. This can be done per target, for example. The illumination configuration may be performed, for example, in a single step with all regions not corresponding to ROIs identified from one acquisition and switched off. Alternatively, the illumination configuration may be performed iteratively with the image checked each iteration (or imaged and checked continuously) for edge effects and/or other unwanted effects till all target regions or pixels are switched off which are not illuminating target regions corresponding to image ROIs. As an alternative (or additional) to such a feedback based illumination calibration, a feed-forward approach may be implemented where each successive measurement is used to update the expected illumination configuration (illumination pixels) for the next measurement; such an approach can result in zero throughput impact after measuring the first target, compared to present overfilled metrology techniques. Another way that acquisition time may be improved is by performing an initial calibration of the illumination configuration for a target, provided that target positioning within the image/detector coordinate system is sufficiently predictable.

An alternative implementation, which may be implemented by simpler illumination arrangements such as presently used spot size selectors, may comprise introducing a suitable pre-configured mask into the illumination (e.g., at an illumination image plane) which is arranged or optimized to illuminate the target or sub-targets in an underfilled manner. For example, for a target comprising four sub-targets of a particular dimension, the mask may comprise four similarly dimension rectangular apertures which exactly illuminate the sub-target regions corresponding to the desired (e.g., μDBO/μDBF) ROIs, without illuminating their edges or other structures (e.g., configures the illumination as illustrated by measurement spots 81 in FIG. 8).

The basic methodology may be the same, e.g., performing an overfilled measurement (e.g., using a conventional measurement spot) to check if positioning is correct, then switching to the configured illumination using the mask. As before, this may be done for only the first measurement, with the positioning corrected on subsequent measurements based on this first measurement and any other previous acquisitions (e.g., provided that target positioning is sufficiently predictable as before).

The disadvantage of this approach compared to a pixelated illuminator (e.g., GLV) approach is that this approach inherently less flexible; the mask or spot size selector would need to be changed for each different target. However, it is simpler and cheaper to implement in hardware.

Intermediate solutions may also be envisaged, such as an “iris” or configurable aperture (e.g., like a camera aperture) which enable specific parametrized size variations of the spot size selector apertures for different targets.

Determining which pixels to switch off via the spot size selector or other illumination arrangement (e.g., at an illumination image plane) may be achieved, for example, in a similar manner to pixel mapping. For example, a method may iteratively switch off pixels and check a performance indicator indicating a good image (e.g., indicating a lack of edge effects or other imaging effects). This may be performed till such edge effects and/or unwanted imaging effects are minimized and/or below a threshold level, for example. This can be done either in-line or in a set-up phase, minimizing throughput loss.

In an optional embodiment, the methods disclosed herein may be combined with a dynamic pupil pixel selection. It should be appreciated that the embodiments up to now above relate to illumination configuration within an image plane of the illumination branch; this is necessary to select only portions of the target for illumination. However, illumination pupil configuration is a known method for reducing edge effects (e.g., using NA-limit apertures) and boosting performance. Configuring the illumination pupil cannot result in selectable illumination of only portions of a target. Furthermore, NA-limit apertures result in a throughput penalty, which dynamic pupil pixel selection would mitigate. The illumination beam profile configuration and dynamic pupil pixel configuration may be co-optimized for minimizing edge effects or other unwanted imaging effects for example. This may be done, for example, based on image acquisition and assessment in an (e.g., iterative) feedback loop till such edge effects and/or unwanted imaging effects are minimized and/or below a threshold level; e.g., as has just been described, but with both dynamic pupil pixel selection and illumination (image plane) pixel selection being varied over the iterations. Alternatively to full co-optimization, each of the optimizations may be performed sequentially.

The concepts disclosed herein are disclosed predominately in terms of overlay metrology. However, the methods are not so limited. For example, targets may be formed with a focus based asymmetry (i.e., asymmetry dependent on the actual scanner focus used to expose the target). The methods disclosed herein can equally be applied to focus metrology (e.g., diffraction based focus DBF or micro-diffraction based focus μDBF) based in such targets, in which case the model determined would be of measurement parameter deviation against inferred focus. Similarly, the concepts disclosed herein may be applied to other (e.g., overlay) target types and metrology techniques such as continuous diffraction based overlay (cDBO) targets, and corresponding cDBO measurement techniques, or image based overlay (IBO) targets and corresponding IBO measurement techniques. Anything imaged in a finite box (e.g., in a field plane) can gain from this approach.

Alternative solutions are conceivable within the context of this disclosure. For example, where the sub-targets each have similar dimensions (as is typical), the illumination may be configured for a single sub-target and divided into multiple beams to illuminate the other sub-targets. For example, where a target comprises four sub-targets, the illumination may be configured according to one of the sub-targets and divided into four beams to illuminate the four sub-targets simultaneously. Similarly, the illumination may be configured according to two of the sub-targets, with this configured illumination doubled to illuminate all four sub-targets. Of course, should the target comprise only two sub-targets, a single configured beam may be split into two configured beams. The splitting of the configured beam may be performed by the metrology tool optics (e.g., using the optical pupil symmetrizer an optical element in some metrology tools which copies the pupil, rotates it through 180 degrees, and overlaps it with the original pupil to make it symmetrical), for example.

Further embodiments according to the present invention are presented in below numbered

### CLAUSES

1. A metrology method comprising:
illuminating a target comprising one or more sub-targets on a substrate using underfilled illumination such that an illumination beam profile underfills each of said one or more sub-targets;
capturing scattered radiation resultant from said illuminating the target;
imaging the scattered radiation at a detection image plane to obtain an image; and
determining a parameter of interest from the imaged scattered radiation.
2. A metrology method according to clause 1, wherein the step of illuminating the target comprises:
configuring the illumination beam profile on the target to illuminate one or more target regions corresponding to one or more regions of interest on a detected image at the detection image plane while minimizing illumination of nuisance structures on said substrate outside of said one or more target regions.
3. A metrology method according to clause 2, wherein the nuisance structures comprise one or more of: at least an edge of the target or of said one or more sub-targets and/or at least one surrounding structure.
4. A metrology method according to any preceding clause, wherein the target comprises two or more sub-targets;
the illuminating step comprises simultaneously illuminating each sub-target using underfilled illumination; and
the capturing step comprises simultaneously capturing scattered radiation resultant from said illuminating each sub-target.
5. A metrology method according to clause 4, wherein the illumination beam profile is configured only for a single or proper subset of said sub-targets; and the illumination beam profile is divided into additional beams to provide illumination for all of said sub-targets.
6. A metrology method according to clause 4 or 5, comprising varying the relative intensities of the illumination illuminating each respective sub-target.
7. A metrology method according to any preceding clause, wherein the method iteratively varies the illumination beam profile and checks a performance indicator indicative of an acceptable image till the image is acceptable according to said performance indicator.
8. A metrology method according to clause 7, wherein said performance indicator comprises a measure of whether edge effects and/or unwanted imaging effects are present in the image.
9. A metrology method according to any preceding clause, wherein the method is performed for a plurality of targets; and
each successive measurement is used to update an expected illumination beam profile for a next measurement.
10. A metrology method according to any preceding clause, comprising performing an initial calibration of the illumination beam profile for the target.
11. A metrology method according to any preceding clause, comprising configuring said illumination beam profile at an illumination image plane.
12. A metrology method according to any preceding clause, comprising configuring said illumination beam profile using a programmable illumination arrangement.
13. A metrology method according to clause 12, wherein said programmable illumination arrangement comprises a spatial light modulator or a grating light valve based illumination arrangement.
14. A metrology method according to any of clauses 1 to 11, comprising configuring said illumination beam profile using a mask comprising one or more apertures optimized for said illumination of the target.
15. A metrology method according to clause 14, wherein said one or more apertures are configurable.
16. A metrology method according to any preceding clause, comprising additionally configuring an illumination pupil of said illumination at an illumination pupil plane.
17. A metrology method according to clause 16, comprising co-optimizing said illumination beam profile and said illumination pupil.
18. A metrology method comprising:
illuminating a target comprising a plurality of sub-targets on a substrate by simultaneously illuminating each sub-target using a configured illumination beam profile which is configured for individually illuminating each of said plurality of sub-targets;
capturing scattered radiation resultant from said illuminating the target; and
determining a parameter of interest from the scattered radiation.
19. A metrology method according to clause 18, wherein the step of illuminating the target comprises:
configuring the illumination beam profile on the target to illuminate a plurality of target regions, each target region corresponding to a respective sub-target of said plurality of sub-targets while minimizing illumination of nuisance structures on said substrate outside of said one or more target regions and/or one or more edges of said sub-target.
20. A metrology method according to clause 18 or 19, wherein the illumination beam profile is configured only for a single or proper subset of said sub-targets; and the illumination beam profile is divided into additional beams to provide illumination for all of said plurality of sub-targets.
21. A metrology method according to any of clauses 18 to 20, wherein the method iteratively varies the illumination beam profile and checks a performance indicator related to the captured scattered radiation till the captured scattered radiation is acceptable according to said performance indicator.
22. A metrology method according to clause 21, wherein said performance indicator comprises a measure of whether edge effects and/or unwanted imaging effects impact the captured scattered radiation.
23. A metrology method according to any of clauses 18 to 22, wherein the method is performed for a plurality of targets; and
each successive measurement is used to update an expected illumination beam profile for a next measurement.
24. A metrology method according to any of clauses 18 to 23, comprising performing an initial calibration of the illumination beam profile for the target.
25. A metrology method according to any of clauses 18 to 24, comprising configuring said illumination beam profile at an illumination image plane.
26. A metrology method according to any of clauses 18 to 25, comprising configuring said illumination beam profile using a programmable illumination arrangement.
27. A metrology method according to clause 26, wherein said programmable illumination arrangement comprises a spatial light modulator or a grating light valve based illumination arrangement.
28. A metrology method according to any of clauses 18 to 25, comprising configuring said illumination beam profile using a mask comprising one or more apertures optimized for said illumination of the target.
29. A metrology method according to clause 28, wherein said one or more apertures are configurable.
30. A metrology method according to any of clauses 18 to 29, comprising additionally configuring an illumination pupil of said illumination at an illumination pupil plane.
31. A metrology method according to clause 30, comprising co-optimizing said illumination beam profile and said illumination pupil.
32. A metrology method according to any preceding clause, comprising varying the relative intensities of the illumination illuminating each respective sub-target.
33. A metrology method according to any preceding clause, wherein the step of illuminating a target comprises simultaneously illuminating each sub-target using underfilled illumination such that the illumination beam profile underfills each of said plurality of sub-targets.
34. A method according to any preceding clause, wherein said parameter of interest is overlay or focus.
35. A method according to any preceding clause, comprising, performing said method inline as part of a lithographic method.
36. A method according to clause 35, further comprising:
exposing said at least one target onto a substrate;
performing said measuring method; and using said parameter of interest value in correcting a subsequent exposing step on a subsequent substrate.
37. A metrology device operable to perform the method of any of clauses 1 to 35.
38. A metrology device according to clause 37, comprising: imaging optics for capturing said scattered radiation from said target; and a detector for detecting the scattered radiation to obtain an image of the target.
39. The metrology device of clause 37 or 38, being a scatterometer.
40. The metrology device of clause 37 or 38, being a dark-field holographic microscope.
41. A lithocell comprising: the metrology device of any of clauses 37 to 40; and a lithographic apparatus.
42. The lithocell of clause 41, being operable to perform the method of clause 36.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of an inspection or metrology apparatus, embodiments of the invention may be used in other apparatus. Embodiments of the invention may form part of a mask inspection apparatus, a lithographic apparatus, or any apparatus that measures or processes an object such as a wafer (or other substrate) or mask (or other patterning device). The term “metrology apparatus” may also refer to an inspection apparatus or an inspection system. E.g. the inspection apparatus that comprises an embodiment of the invention may be used to detect defects of a substrate or defects of structures on a substrate. In such an embodiment, a characteristic of interest of the structure on the substrate may relate to defects in the structure, the absence of a specific part of the structure, or the presence of an unwanted structure on the substrate.

Although specific reference is made to “metrology apparatus/tool/system” or “inspection apparatus/tool/system”, these terms may refer to the same or similar types of tools, apparatuses or systems. E.g. the inspection or metrology apparatus that comprises an embodiment of the invention may be used to determine characteristics of structures on a substrate or on a wafer. E.g. the inspection apparatus or metrology apparatus that comprises an embodiment of the invention may be used to detect defects of a substrate or defects of structures on a substrate or on a wafer. In such an embodiment, a characteristic of interest of the structure on the substrate may relate to defects in the structure, the absence of a specific part of the structure, or the presence of an unwanted structure on the substrate or on the wafer.

Although specific reference may have been made above to the use of embodiments of the invention in the context of optical lithography, it will be appreciated that the invention, where the context allows, is not limited to optical lithography and may be used in other applications, for example imprint lithography.

While the targets or target structures (more generally structures on a substrate) described above are metrology target structures specifically designed and formed for the purposes of measurement, in other embodiments, properties of interest may be measured on one or more structures which are functional parts of devices formed on the substrate. Many devices have regular, grating-like structures. The terms structure, target grating and target structure as used herein do not require that the structure has been provided specifically for the measurement being performed. Further, pitch P of the metrology targets may be close to the resolution limit of the optical system of the scatterometer or may be smaller, but may be much larger than the dimension of typical product features made by lithographic process in the target portions C. In practice the lines and/or spaces of the overlay gratings within the target structures may be made to include smaller structures similar in dimension to the product features.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1-15. (canceled)

16. A metrology method comprising:
illuminating a target comprising one or more sub-targets on a substrate using underfilled illumination such that an illumination beam profile underfills each of the one or more sub-targets;
capturing scattered radiation resultant from the illuminating the target;
imaging the scattered radiation at a detection image plane to obtain an image; and
determining a parameter of interest from the image.

17. The metrology method of claim 16, wherein the illuminating the target comprises:
configuring the illumination beam profile on the target to illuminate one or more target regions corresponding to one or more regions of interest on a detected image at the detection image plane while minimizing illumination of nuisance structures on the substrate outside of the one or more target regions.

18. The metrology method of claim 17, wherein the nuisance structures comprise one or more of: at least an edge of the target or of the one or more sub-targets and/or at least one surrounding structure.

19. The metrology method of claim 16, wherein:
the target comprises two or more sub-targets;
the illuminating comprises substantially simultaneously illuminating each sub-target using underfilled illumination; and
the capturing comprises substantially simultaneously capturing scattered radiation resultant from the illuminating each sub-target.

20. The metrology method of claim 19, wherein:
the illumination beam profile is configured for a single or proper subset of the sub-targets; and
the illumination beam profile is divided into additional beams to provide illumination for all of the sub-targets.

21. The metrology method of claim 19, further comprising varying the relative intensities of the illumination illuminating each respective sub-target.

22. The metrology method of claim 16, further comprising:
iteratively varying the illumination beam profile; and
checking a performance indicator indicative of an acceptable image until the image is acceptable according to the performance indicator.

23. The metrology method of claim 22, wherein the performance indicator comprises a measure of whether edge effects and/or unwanted imaging effects are present in the image.

24. The metrology method of claim 16, further comprising:
performing the method for a plurality of targets; and
wherein each successive measurement is used to update an expected illumination beam profile for a next measurement.

25. The metrology method of claim 16, further comprising performing an initial calibration of the illumination beam profile for the target.

26. The metrology method of claim 16, further comprising configuring the illumination beam profile at an illumination image plane.

27. The metrology method of claim 16, further comprising configuring the illumination beam profile using a programmable illumination arrangement.

28. The metrology method of claim 27, wherein the programmable illumination arrangement comprises using a spatial light modulator or a grating light valve based illumination arrangement.

29. The metrology method of claim 16, further comprising configuring the illumination beam profile using a mask comprising one or more apertures optimized for the illumination of the target.

30. The metrology method as of claim 29, wherein the one or more apertures are configurable.

31. The metrology method of claim 16, further comprising additionally configuring an illumination pupil of the illumination at an illumination pupil plane.

32. The metrology method of claim 31, further comprising co-optimizing the illumination beam profile and the illumination pupil.

33. The metrology method of claim 16, further comprising varying the relative intensities of the illumination illuminating each respective sub-target.

34. The metrology method of claim 16, wherein the illuminating the target comprises simultaneously illuminating each sub-target using underfilled illumination such that the illumination beam profile underfills each of the plurality of sub-targets.

35. The method of claim 16, wherein the parameter of interest is overlay or focus.
